(19) United States
(12) Patent Application Publication
(10) Pub. No.: US 2017/0267518 A1
(43) Pub. Date: Sep. 21, 2017

(54) PRESSURE SENSOR, PRODUCTION METHOD FOR PRESSURE SENSOR, ALTIMETER, ELECTRONIC APPARATUS, AND MOVING OBJECT

(71) Applicant: SEIKO EPSON CORPORATION, Tokyo (JP)

(72) Inventors: Takuya KINUGAWA, Suwa-shi (JP); Yusuke MATSUZAWA, Chino-shi (JP); Hiroyuki SHIMADA, Chuo-shi (JP)

(73) Assignee: SEIKO EPSON CORPORATION, Tokyo (JP)

(21) Appl. No.: 15/443,320

(22) Filed: Feb. 27, 2017

(30) Foreign Application Priority Data
Mar. 15, 2016 (JP) 2016-050558

(51) Int. Cl. B81B 7/00; B81C 1/00

(52) U.S. Cl. CPC B81B 7/0038; B81C 1/00666; B81B 2203/0127; B81B 2201/0264; B81B 2201/0292; B81C 2203/019

(57) ABSTRACT

A pressure sensor includes a silicon substrate which has a diaphragm, a frame-shaped side wall section which is placed on one surface side of the silicon substrate so as to surround the diaphragm in a plan view, a lid section which is placed so as to cover an opening of the side wall section and has a through-hole communicating inside and outside the side wall section, a sealing section which is placed on the lid section and seals the through-hole, and a pressure reference chamber which is defined by the silicon substrate, the side wall section, the lid section, and the sealing section, wherein a surface facing the pressure reference chamber of each of the side wall section and the lid section contains a silicon material.

### BACKGROUND

1. Technical Field

The present invention relates to a pressure sensor, a production method for a pressure sensor, an altimeter, an electronic apparatus, and a moving object.

2. Related Art

There has been known a configuration described in JP-A-2015-175833 (Patent Document 1) as a pressure sensor. The pressure sensor described in Patent Document 1 includes a silicon substrate having a diaphragm which is flexurally deformed by receiving a pressure, and a pressure reference chamber which is placed on the diaphragm and is defined by a structure composed of aluminum. Such a pressure sensor is configured to measure a pressure by detecting the flexural deformation of the diaphragm by receiving the pressure with a piezoelectric element placed in the diaphragm.

However, in the pressure sensor having such a configuration, the diaphragm is composed of silicon and the structure is composed of aluminum, and therefore, due to the difference in the thermal expansion coefficient of these materials (Si: 2.6 ppm/K, Al: 23 ppm/K), the internal stress of the diaphragm greatly changes depending on the environmental temperature. Therefore, there is a problem that a hysteresis in which even if the same pressure is received, the measured value varies depending on the environmental temperature occurs. In a more serious case, a temperature characteristic curve may sometimes changes depending on the thermal history. In such a case, it cannot be corrected even by a correction circuit or the like.

### SUMMARY

An advantage of some aspects of the invention is to provide a pressure sensor capable of reducing the hysteresis, a production method for the pressure sensor, and an altimeter, an electronic apparatus, and a moving object, each of which includes the pressure sensor and has high reliability.

The advantage can be achieved by the following configuration.

A pressure sensor according to an aspect of the invention includes a silicon substrate which has a diaphragm that is flexurally deformed by receiving a pressure, a frame-shaped side wall section which is placed on one surface side of the silicon substrate so as to surround the diaphragm in a plan view, a lid section which is placed so as to cover an opening of the side wall section and has a through-hole communicating inside and outside the side wall section, a sealing section which is placed on the opposite side to the silicon substrate of the lid section and seals the through-hole, and a pressure reference chamber which is defined by the silicon substrate, the side wall section, the lid section, and the sealing section, wherein a portion on a surface side facing the pressure reference chamber of each of the side wall section and the lid section contains a silicon material.

According to this configuration, a pressure sensor capable of reducing the hysteresis is obtained.

In the pressure sensor according to the aspect of the invention, it is preferred that the side wall section includes a base section which contains silicon oxide, and a coating layer which is placed on a surface of the base section so as to face the pressure reference chamber, and contains silicon.

According to this configuration, the side wall section is easily formed.

In the pressure sensor according to the aspect of the invention, it is preferred that the coating layer and the lid section are formed as one body.

According to this configuration, the coating layer and the lid section can be formed in the same step, and therefore, the production of the pressure sensor can be simplified.

In the pressure sensor according to the aspect of the invention, it is preferred that the sealing section contains a silicon material.

According to this configuration, the hysteresis can be further reduced.

In the pressure sensor according to the aspect of the invention, it is preferred that the side wall section has a tapered shape in which the width of the pressure reference chamber gradually decreases from the diaphragm side to the lid section side.

According to this configuration, the size of the lid section can be decreased, and therefore, the flexure of the lid section can be reduced.

A production method for a pressure sensor according to an aspect of the invention includes preparing a silicon substrate which has a diaphragm forming region, placing a sacrificial layer on one surface side of the silicon substrate so as to overlap the diaphragm forming region in a plan view, placing a first silicon material layer containing a silicon material on a surface of the sacrificial layer, placing a second silicon material layer containing a silicon material so as to cover the first silicon material layer, removing a portion of the second silicon material layer, thereby exposing the first silicon material layer from the removed portion, forming a through-hole facing the sacrificial layer in a portion exposed from the second silicon material layer of the first silicon material layer, forming a pressure reference chamber by removing the sacrificial layer through the through-hole, sealing the through-hole by placing a sealing section in the portion exposed from the second silicon material layer of the first silicon material layer, and forming a diaphragm which is flexurally deformed by receiving a pressure in the diaphragm forming region of the silicon substrate.

According to this configuration, a pressure sensor capable of reducing the hysteresis can be relatively easily produced.

In the production method for a pressure sensor according to the aspect of the invention, it is preferred that the sacrificial layer has a tapered shape in which the width thereof gradually decreases along a separating direction from the silicon substrate.

According to this configuration, the first silicon material layer is easily placed on a side surface of the sacrificial layer.

A production method for a pressure sensor according to an aspect of the invention includes preparing a silicon substrate which has a diaphragm forming region, placing a frame-shaped side wall section containing a silicon material on one surface side of the silicon substrate so as to surround the diaphragm forming region in a plan view, placing a sacrificial layer inside the side wall section, placing a lid section which has a through-hole facing the sacrificial layer and contains a silicon material on the side wall section and the sacrificial layer so as to cover an opening of the side wall section, forming a pressure reference chamber by removing the sacrificial layer through the through-hole, sealing the through-hole by placing a sealing section on the lid section, and forming a diaphragm which is flexurally deformed by receiving a pressure in the diaphragm forming region of the silicon substrate.

According to this configuration, a pressure sensor capable of reducing the hysteresis can be relatively easily produced.

In the production method for a pressure sensor according to the aspect of the invention, it is preferred that in the placing the sacrificial layer, the sacrificial layer is placed so as to fill the inside of the side wall section and also cover the surface on the opposite side to the silicon substrate of the side wall section, and in the placing the lid section, a frame-shaped through-hole facing the side wall section is formed in a portion overlapping the side wall section of the sacrificial layer, and the lid section is placed in the frame-shaped through-hole and on the sacrificial layer.

According to this configuration, a surface on the opposite side to the silicon substrate of the side wall section can be protected.

An altimeter according to an aspect of the invention includes the pressure sensor according to the aspect of the invention.

According to this configuration, an altimeter having high reliability is obtained.

An electronic apparatus according to an aspect of the invention includes the pressure sensor according to the aspect of the invention.

According to this configuration, an electronic apparatus having high reliability is obtained.

A moving object according to an aspect of the invention includes the pressure sensor according to the aspect of the invention.

According to this configuration, a moving object having high reliability is obtained.

### BRIEF DESCRIPTION OF THE DRAWINGS

The invention will be described with reference to the accompanying drawings, wherein like numbers reference like elements.

FIG. 1 is a cross-sectional view showing a pressure sensor according to a first embodiment of the invention.

FIG. 2 is a plan view showing a pressure sensor section included in the pressure sensor shown in FIG. 1.

FIG. 3 is a view showing a bridge circuit including the pressure sensor section shown in FIG. 2.

FIG. 4 is a flowchart showing a production method for the pressure sensor shown in FIG. 1.

FIG. 5 is a cross-sectional view for illustrating the production method for the pressure sensor shown in FIG. 1.

FIG. 6 is a cross-sectional view for illustrating the production method for the pressure sensor shown in FIG. 1.

FIG. 7 is a cross-sectional view for illustrating the production method for the pressure sensor shown in FIG. 1.

FIG. 8 is a cross-sectional view for illustrating the production method for the pressure sensor shown in FIG. 1.

FIG. 9 is a cross-sectional view for illustrating the production method for the pressure sensor shown in FIG. 1.

FIG. 10 is a cross-sectional view for illustrating the production method for the pressure sensor shown in FIG. 1.

FIG. 11 is a cross-sectional view for illustrating the production method for the pressure sensor shown in FIG. 1.

FIG. 12 is a cross-sectional view for illustrating the production method for the pressure sensor shown in FIG. 1.

FIG. 13 is a cross-sectional view for illustrating the production method for the pressure sensor shown in FIG. 1.

FIG. 14 is a cross-sectional view for illustrating the production method for the pressure sensor shown in FIG. 1.

FIG. 15 is a cross-sectional view for illustrating the production method for the pressure sensor shown in FIG. 1.

FIG. 16 is a cross-sectional view for illustrating the production method for the pressure sensor shown in FIG. 1.

FIG. 17 is a cross-sectional view for illustrating the production method for the pressure sensor shown in FIG. 1.

FIG. 18 is a cross-sectional view for illustrating the production method for the pressure sensor shown in FIG. 1.

FIG. 19 is a cross-sectional view showing a pressure sensor according to a second embodiment of the invention.

FIG. 20 is a flowchart showing a production method for the pressure sensor shown in FIG. 19.

FIG. 21 is a cross-sectional view for illustrating the production method for the pressure sensor shown in FIG. 19.

FIG. 22 is a cross-sectional view for illustrating the production method for the pressure sensor shown in FIG. 19.

FIG. 23 is a cross-sectional view for illustrating the production method for the pressure sensor shown in FIG. 19.

FIG. 24 is a cross-sectional view for illustrating the production method for the pressure sensor shown in FIG. 19.

FIG. 25 is a cross-sectional view for illustrating the production method for the pressure sensor shown in FIG. 19.

FIG. 26 is a cross-sectional view for illustrating the production method for the pressure sensor shown in FIG. 19.

FIG. 27 is a cross-sectional view for illustrating the production method for the pressure sensor shown in FIG. 19.

FIG. 28 is a cross-sectional view for illustrating the production method for the pressure sensor shown in FIG. 19.

FIG. 29 is a cross-sectional view for illustrating the production method for the pressure sensor shown in FIG. 19.

FIG. 30 is a cross-sectional view showing a pressure sensor according to a third embodiment of the invention.

FIG. 31 is a cross-sectional view for illustrating a production method for the pressure sensor shown in FIG. 30.

FIG. 32 is a cross-sectional view for illustrating the production method for the pressure sensor shown in FIG. 30.

FIG. 33 is a cross-sectional view for illustrating the production method for the pressure sensor shown in FIG. 30.

FIG. 34 is a cross-sectional view for illustrating the production method for the pressure sensor shown in FIG. 30.

FIG. 35 is a cross-sectional view for illustrating the production method for the pressure sensor shown in FIG. 30.

FIG. 36 is a perspective view showing one example of an altimeter according to the invention.

FIG. 37 is a front view showing one example of an electronic apparatus according to the invention.

FIG. 38 is a perspective view showing one example of a moving object according to the invention.

### DESCRIPTION OF EXEMPLARY EMBODIMENTS

Hereinafter, a pressure sensor, a production method for a pressure sensor, an altimeter, an electronic apparatus, and a moving object according to the invention will be described in detail based on embodiments shown in the accompanying drawings.

### First Embodiment

First, a pressure sensor according to a first embodiment of the invention will be described.

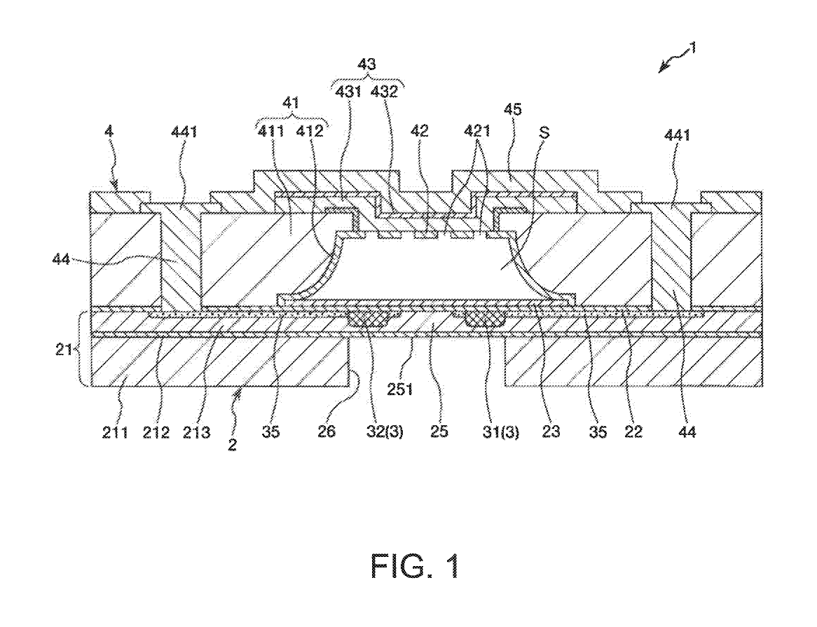

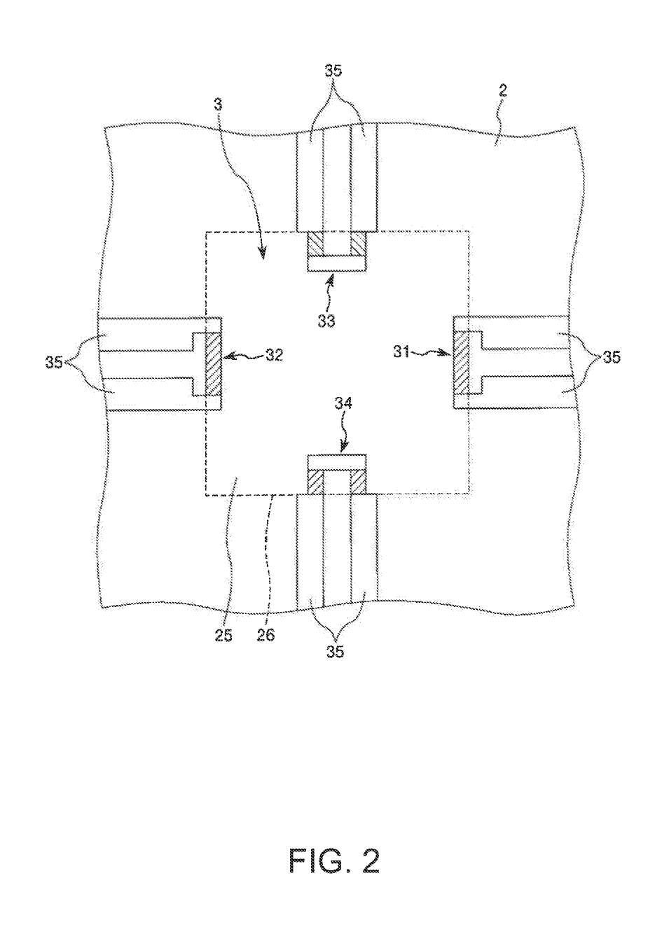

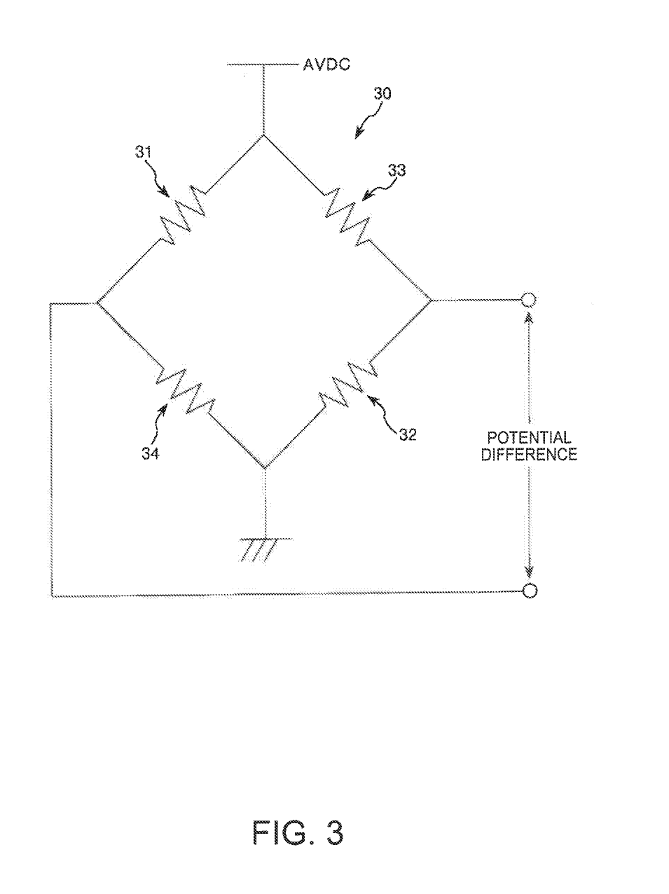

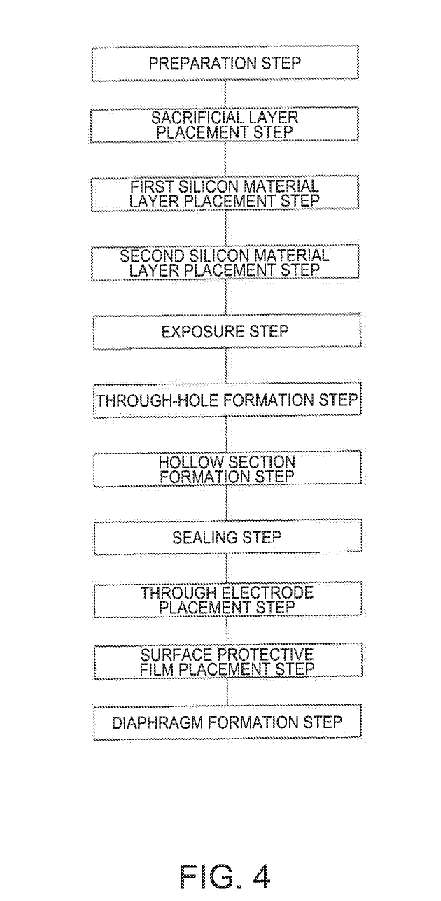

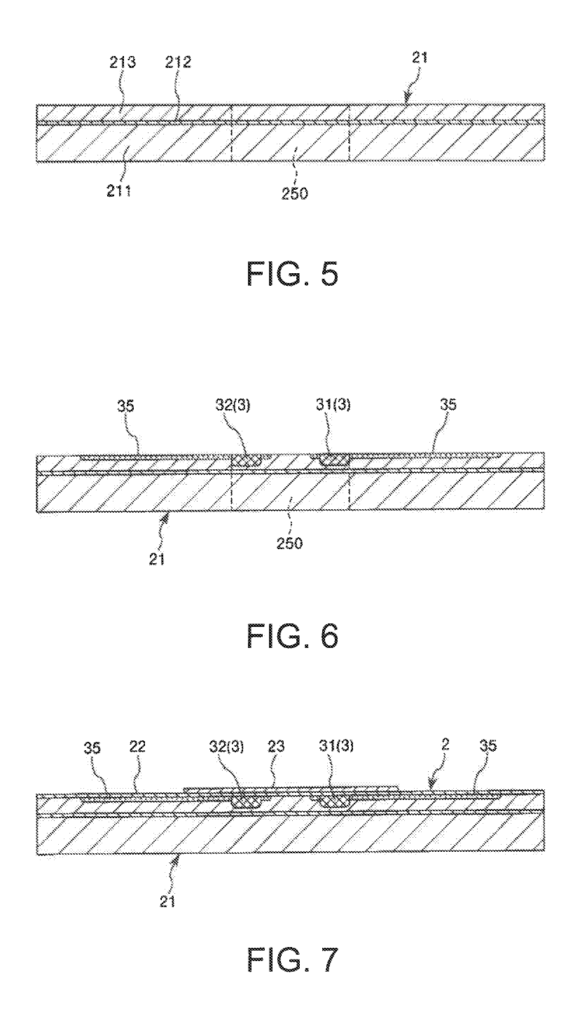

FIG. 1 is a cross-sectional view showing the pressure sensor according to the first embodiment of the invention. FIG. 2 is a plan view showing a pressure sensor section included in the pressure sensor shown in FIG. 1. FIG. 3 is a view showing a bridge circuit including the pressure sensor section shown in FIG. 2. FIG. 4 is a flowchart showing a production method for the pressure sensor shown in FIG. 1. FIGS. 5 to 18 are each a cross-sectional view for illustrating the production method for the pressure sensor shown in FIG. 1. In the following description, the upper side and the lower side in FIG. 1 are also referred to as “upper” and “lower”, respectively.

A pressure sensor 1 shown in FIG. 1 includes an SOI substrate 21 as a silicon substrate which has a diaphragm 25 that is flexurally deformed by receiving a pressure, a frame-shaped side wall section 41 which is placed on one surface side of the SOI substrate 21 so as to surround the diaphragm 25 in a plan view, a lid section 42 which is placed so as to cover an opening of the side wall section 41 and has a through-hole 421 communicating inside and outside the side wall section 41, a sealing section 43 which is placed on the opposite side to the SOI substrate 21 of the lid section 42 and seals the through-hole 421, and a hollow section S as a pressure reference chamber which is defined by the SOI substrate 21, the side wall section 41, the lid section 42, and the sealing section 43, and a portion on a surface side facing the hollow section S of each of the side wall section 41 and the lid section 42 contains a silicon material. According to this, a pressure sensor 1 capable of reducing the hysteresis is obtained. Hereinafter, such a pressure sensor 1 will be described in detail.

The pressure sensor 1 shown in FIG. 1 includes a base 2, a pressure sensor section 3, a surrounding structure 4, and a hollow section S.

### Base

As shown in FIG. 1, the base 2 is constituted by stacking a first insulating film 22 constituted by a silicon oxide film (SiO₂ film) and a second insulating film 23 constituted by polysilicon in this order on the SOI substrate 21. The SOI substrate 21 includes a first silicon layer 211, a second silicon layer 213 placed on the upper side of the first silicon layer 211, and a silicon oxide layer 212 placed between the first and second silicon layers 211 and 213. The silicon substrate is not limited to the SOI substrate. The first insulating film 22 and the second insulating film 23 may be provided as needed and may be omitted.

Further, in the SOI substrate 21, a diaphragm 25 which is thinner than the peripheral portion and is flexurally deformed by receiving a pressure is provided. By providing a bottomed concave section 26 which opens to the lower surface of the SOI substrate 21, this diaphragm 25 is formed as a bottom portion of the concave section 26. Then, the lower surface of the diaphragm 25 becomes a pressure receiving surface 251. The thickness of the diaphragm 25 is not particularly limited, but is preferably set to about 1.5 μm or more and 2.0 μm or less. According to this, the diaphragm 25 which is easy to flex while sufficiently maintaining the mechanical strength is formed.

### Pressure Sensor Section

As shown in FIG. 2, the pressure sensor section 3 includes four piezoresistive elements 31, 32, 33, and 34 provided in the diaphragm 25. The piezoresistive elements 31, 32, 33, and 34 are electrically connected to one another through a wiring 35 or the like and constitute a bridge circuit 30 (Wheatstone bridge circuit) shown in FIG. 3.

To the bridge circuit 30, a drive circuit (not shown) which supplies a drive voltage AVDC is connected. Then, the bridge circuit 30 outputs a signal in accordance with the change in the resistance value of the piezoresistive element 31, 32, 33, or 34 based on the flexure of the diaphragm 25. Due to this, a pressure received by the diaphragm 25 can be detected based on this output signal.

Each of the piezoresistive elements 31, 32, 33, and 34 is constituted by, for example, doping (diffusing or injecting) an impurity such as phosphorus or boron into the second silicon layer 213. The wiring 35 is constituted by, for example, doping (diffusing or injecting) an impurity such as phosphorus or boron into the second silicon layer 213 at a higher concentration than in the piezoresistive elements 31 to 34.

### Hollow Section

As shown in FIG. 1, the hollow section S is defined by being surrounded by the base 2 and the surrounding structure 4. Such a hollow section S is a hermetically sealed space and functions as a pressure reference chamber which provides a reference value of a pressure to be detected by the pressure sensor 1. Further, the hollow section S is located on the opposite side to the pressure receiving surface 251 of the diaphragm 25 and is placed so as to overlap the diaphragm 25. The hollow section S is preferably in a vacuum state (for example, about 10 Pa or less). According to this, the pressure sensor 1 can be used as a so-called “absolute pressure sensor” which detects a pressure with reference to vacuum, and the pressure sensor 1 which has high convenience is formed. However, the hollow section S may not be in a vacuum state as long as the pressure is kept constant therein.

### Surrounding Structure

The surrounding structure 4 forms the hollow section S between the same and the base 2. As shown in FIG. 1, such a surrounding structure 4 is provided on the upper surface of the base 2. Further, the surrounding structure 4 includes the frame-shaped side wall section 41 which is placed on the upper surface (one surface) of the base 2 so as to surround the diaphragm 25 in a plan view, the lid section 42 which is placed so as to cover an opening on the upper side of the side wall section 41, and has a through-hole 421 communicating inside and outside the hollow section S (that is, inside and outside the side wall section 41), the sealing section 43 which is placed on the lid section 42 and seals the through-hole 421, a through electrode 44 which is electrically connected to the wiring 35 of the pressure sensor section 3, and a surface protective film 45 which is placed on the surface of each of the side wall section 41 and the sealing section 43. Then, the hollow section S is defined by being surrounded by the base 2, the side wall section 41, the lid section 42, and the sealing section 43.

The inner periphery of a lower end portion of the side wall section 41 has a larger size than the diaphragm 25 in a plan view, and the entire region of the diaphragm 25 is included in the inside. Further, the side wall section 41 has a tapered shape in which the width of the hollow section S gradually decreases from the lower side (the diaphragm 25 side) to the upper side (the lid section 42 side). In this manner, by forming the side wall section 41 into a tapered shape, the size of the lid section 42 can be decreased, and the flexure of the lid section 42 can be reduced. Due to this, for example, the contact of the lid section 42 with the diaphragm 25 or the non-detachment of the lid section 42 while being in contact with the diaphragm 25, in other words, the occurrence of so-called “sticking” can be reduced. In particular, in this embodiment, the inner peripheral surface of the side wall section 41 is a curved surface which is convexly curved toward the hollow section S, and therefore, the volume of the hollow section S can be reduced. Due to this, the replacement of the atmosphere in the hollow section S can be efficiently performed. However, the shape of the side wall section 41 is not limited to the shape in this embodiment.

Such a side wall section 41 includes a frame-shaped base section 411 and a coating layer 412 which is placed on the surface of the base section 411, specifically, on the inner peripheral surface of the base section 411, and the coating layer 412 faces the hollow section S. Further, the base section 411 contains silicon oxide, and is particularly composed of silicon oxide in this embodiment. On the other hand, the coating layer 412 contains silicon, and is particularly composed of polysilicon in this embodiment. In this manner, by containing a silicon material in the base section 411 and the coating layer 412, the difference in the thermal expansion coefficient between the side wall section 41 and the base 2 can be decreased. Due to this, the hysteresis of the pressure sensor 1 can be further reduced as described later. In addition, the configuration of the side wall section 41 becomes simple, and therefore, the production of the side wall section 41 is facilitated. The constituent materials of the base section 411 and the coating layer 412 are not particularly limited, and may be, for example, single-crystal silicon, amorphous silicon, silicon nitride, or the like.

The lid section 42 is located on the ceiling of the hollow section S, and is placed so as to cover the opening on the upper side of the side wall section 41. Further, in the lid section 42, the through-hole 421 communicating inside and outside the hollow section S is provided. The through-hole 421 is used as a release hole for removing a sacrificial layer when forming the hollow section S as described later. Such a lid section 42 contains a silicon material, and is particularly composed of polysilicon in this embodiment. In this manner, by containing a silicon material in the lid section 42, the difference in the thermal expansion coefficient between the lid section 42 and the base 2 can be decreased. Due to this, the hysteresis of the pressure sensor 1 can be further reduced as described later. The constituent material of the lid section 42 is not particularly limited, and may be, for example, single-crystal silicon, amorphous silicon, silicon nitride, or the like.

In this manner, in the pressure sensor 1, the surface facing the hollow section S of each of the base 2, the side wall section 41, and the lid section 42 contains a silicon material, and therefore, the difference in the thermal expansion coefficient of a portion which defines the hollow section S can be decreased. Due to this, the hysteresis problem (such as a phenomenon in which even if the same pressure is received, the measured value varies depending on the thermal history) caused in the case where the thermal expansion coefficient of the portion which defines the hollow section S as in the “Related Art” described above hardly occurs. Due to this, according to the pressure sensor 1, the hysteresis can be reduced, and the decrease in the pressure detection accuracy can be effectively reduced.

In particular, in this embodiment, the lid section 42 and the coating layer 412 are formed as one body. That is, the lid section 42 and the coating layer 412 are integrally formed. According to this, as will also be described in the below-mentioned production method, the lid section 42 and the coating layer 412 can be formed in the same step, and therefore, the production of the pressure sensor 1 can be simplified. Further, a connection portion is not formed in a boundary portion between the lid section 42 and the coating layer 412, and therefore, a risk that a gap is generated in the portion is reduced, and therefore, the leakage of an etching solution can be reduced. This will be described in the below-mentioned production method.

On such a lid section 42, the sealing section 43 is placed, and by the sealing section 43, the through-hole 421 is sealed. The sealing section 43 contains a silicon material, and particularly has a stacked structure of a first sealing layer 431 composed of silicon and a second sealing layer 432 composed of silicon oxide in this embodiment. In this manner, by containing a silicon material in the sealing section 43, the difference in the thermal expansion coefficient of the sealing section 43, the side wall section 41, the lid section 42, and the base 2 can be decreased. Due to this, the hysteresis of the pressure sensor 1 can be more effectively reduced. The configuration of the sealing section 43 is not particularly limited, and may not be a stacked structure as in this embodiment, and may be a single layer structure.

The through electrode 44 is placed passing through the base section 411 of the side wall section 41, and the lower end portion thereof is electrically connected to the wiring 35 of the pressure sensor section 3, and the upper end portion thereof becomes a terminal 441 exposed on the upper surface of the surrounding structure 4. Due to this, through the through electrode 44, the pressure sensor section 3 and an external device (for example, an IC) can be electrically connected to each other. As the constituent material of such a through electrode 44, a metal material such as aluminum can be used.

The surface protective film 45 has a function to protect the surrounding structure 4 from water, dust, scratches, etc. Such a surface protective film 45 is placed so as to cover the surface of each of the side wall section 41 and the sealing section 43. The constituent material of such a surface protective film 45 is not particularly limited, and for example, a silicon-based material such as silicon oxide or silicon nitride, any of various types of resin materials such as polyimide or an epoxy resin, or the like can be used. As the constituent material of such a surface protective film 45, particularly, a silicon-based material is preferred. In this manner, by containing a silicon material in the surface protective film 45, the difference in the thermal expansion coefficient between the surface protective film 45 and the other members (such as the sealing section 43, the side wall section 41, the lid section 42, and the base 2) can be decreased. Due to this, the hysteresis of the pressure sensor 1 can be more effectively reduced.

Next, a production method for the pressure sensor 1 will be described. As shown in FIG. 4, the production method for the pressure sensor 1 includes a preparation step of preparing the SOI substrate 21 as the silicon substrate having a diaphragm forming region 250, a sacrificial layer placement step of placing the sacrificial layer 50 on one surface side of the SOI substrate 21 so as to overlap the diaphragm forming region 250 in a plan view, a first silicon material layer placement step of placing the first silicon material layer 51 containing a silicon material on the surface of the sacrificial layer 50, a second silicon material layer placement step of placing the second silicon material layer 52 containing a silicon material so as to cover the first silicon material layer 51, an exposure step of removing a portion of the second silicon material layer 52, thereby exposing the first silicon material layer 51 from the removed portion, a through-hole formation step of forming the through-hole 421 facing the sacrificial layer 50 in a portion exposed from the second silicon material layer 52 of the first silicon material layer 51, a hollow section formation step of forming the hollow section S as the pressure reference chamber by removing the sacrificial layer 50 through the through-hole 421, a sealing step of sealing the through-hole 421 by placing the sealing section 43 in the portion exposed from the second silicon material layer 52 of the first silicon material layer 51, a through electrode placement step of placing the through electrode 44, a surface protective film placement step of placing the surface protective film 45, and a diaphragm formation step of forming the diaphragm 25 which is flexurally deformed by receiving a pressure in the diaphragm forming region 250 of the SOI substrate 21.

### Preparation Step

First, as shown in FIG. 5, the SOI substrate 21 in which the first silicon layer 211, the silicon oxide layer 212, and the second silicon layer 213 are stacked is prepared. In this SOI substrate 21, the diaphragm forming region 250 for forming the diaphragm 25 has been set. Subsequently, as shown in FIG. 6, the pressure sensor section 3 is formed by injecting an impurity such as phosphorus or boron into the upper surface of the SOI substrate 21. Subsequently, as shown in FIG. 7, the first insulating film 22 and the second insulating film 23 are sequentially formed on the SOI substrate 21 using a sputtering method, a CVD method, or the like. By doing this, the base 2 in a state where the diaphragm 25 is not formed is obtained.

### Sacrificial Layer Placement Step

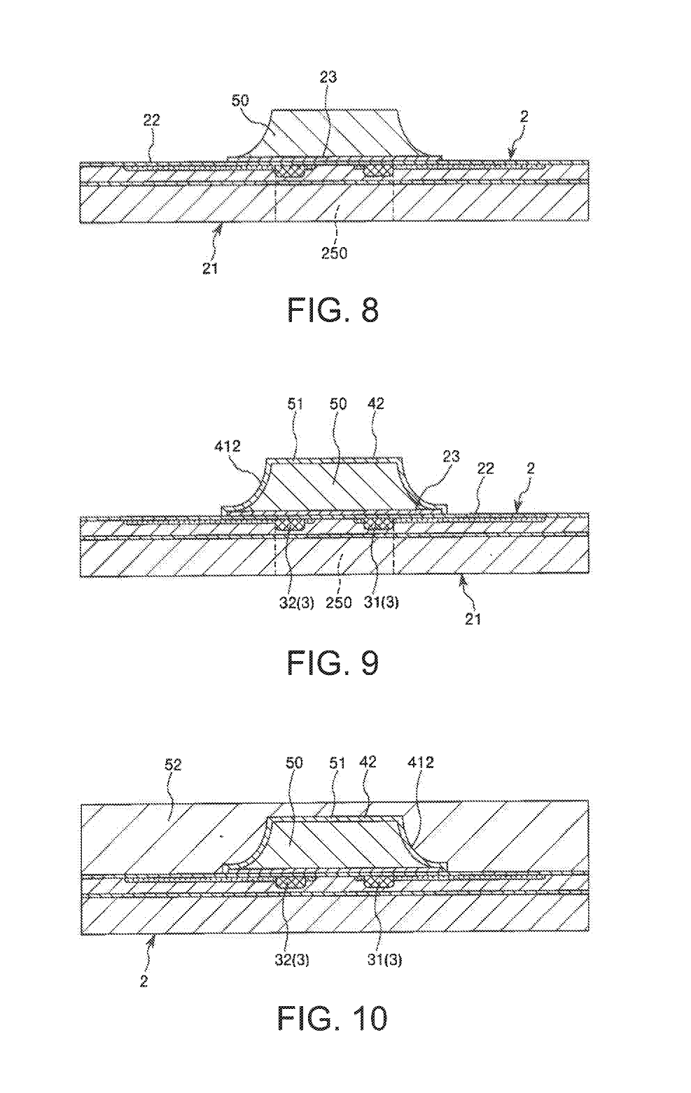

Subsequently, as shown in FIG. 8, the sacrificial layer 50 is placed on the upper surface of the base 2 so as to enclose and overlap the entire region of the diaphragm forming region 250 in a plan view. The placed sacrificial layer 50 has a tapered shape in which the width thereof gradually decreases upward (that is, along a separating direction from the SOI substrate 21). Such a sacrificial layer 50 is not particularly limited as long as it can be removed in the hollow section formation step to be performed later, but can be constituted by a SiO₂ layer formed by a CVD method or the like using TEOS (tetraethoxysilane) in this embodiment. The thickness of the sacrificial layer 50 is not particularly limited, but can be set to about 50 μm.

### First Silicon Material Layer Placement Step

Subsequently, as shown in FIG. 9, the first silicon material layer 51 containing a silicon material is formed on the surface (that is, the upper surface and the side surface) of the sacrificial layer 50 using a sputtering method, a CVD method, or the like. Here, the sacrificial layer 50 has a tapered shape in which the width thereof gradually decreases upward as described above, and therefore, the first silicon material layer 51 is easily formed also on the side surface of the sacrificial layer 50.

In this step, the first silicon material layer 51 is formed extending over the side surface of the sacrificial layer 50 and the upper surface of the base 2, and the first silicon material layer 51 and the second insulating film 23 are connected to each other. According to this, the sacrificial layer 50 is in a state where the entire circumference thereof is covered with the second insulating film 23 and the first silicon material layer 51.

As the constituent material of the first silicon material layer 51, a material having high etching selectivity to the sacrificial layer 50 is preferably selected, and polysilicon is used in this embodiment. By using polysilicon as the constituent material of the first silicon material layer 51, the constituent materials of the first silicon material layer 51 and the second insulating film 23 can be made the same, and therefore, the bondability thereof is improved, and the leakage of an etching solution from the boundary portion thereof can be effectively reduced in the hollow section formation step to be performed later.

By such a first silicon material layer 51, the lid section 42 and the coating layer 412 can be integrally formed. Specifically, a portion located in the upper surface of the first silicon material layer 51 becomes the lid section 42, and a portion located in the side surface becomes the coating layer 412. According to such a method, the lid section 42 and the coating layer 412 can be formed in the same step, and therefore, the production of the pressure sensor 1 can be simplified. Further, a connection portion is not formed in a boundary portion between the lid section 42 and the coating layer 412, and therefore, a risk that a gap is generated in the portion is reduced. Due to this, the leakage of an etching solution can be effectively reduced in the hollow section formation step to be performed later.

### Second Silicon Material Layer Placement Step

Subsequently, as shown in FIG. 10, the second silicon material layer 52 containing a silicon material is placed so as to cover the first silicon material layer 51, and thereafter, the upper surface thereof is flattened by CMP (chemical mechanical polishing) or the like. The second silicon material layer 52 is not particularly limited, but can be constituted by a SiO₂ layer formed by a CVD method or the like using TEOS (tetraethoxysilane) in this embodiment.

### Exposure Step

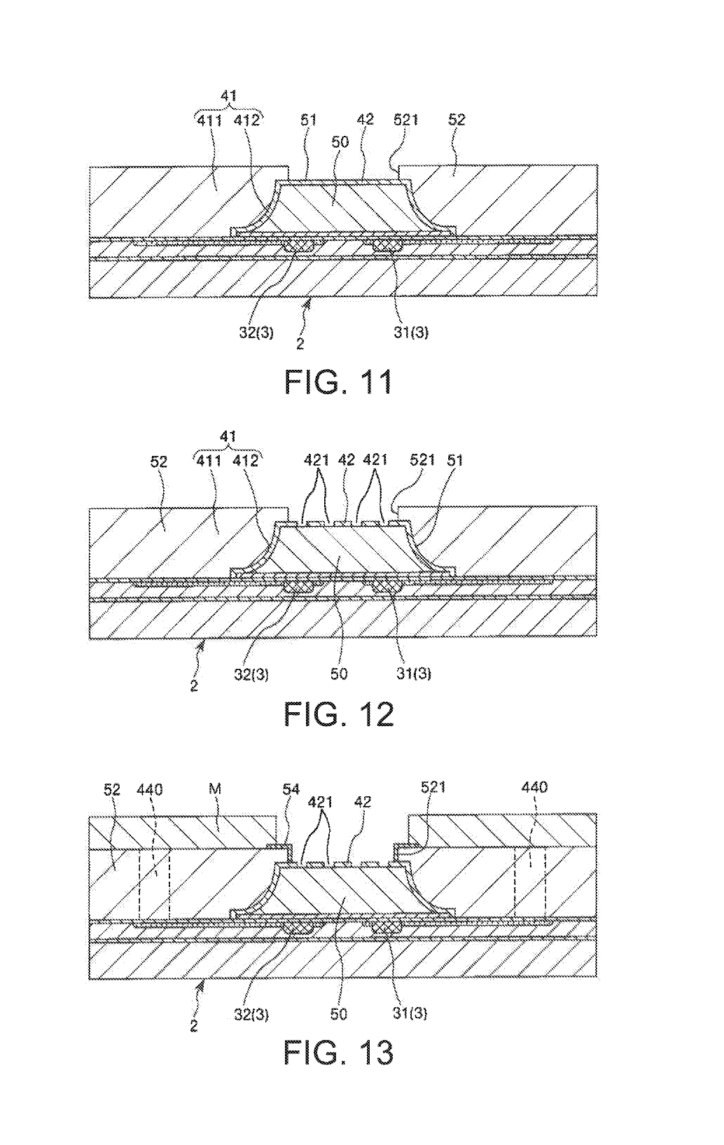

Subsequently, as shown in FIG. 11, a through-hole 521 is formed by removing a portion of the second silicon material layer 52, and the lid section 42 which is the upper surface of the first silicon material layer 51 is exposed from the through-hole 521. By doing this, the base section 411 constituted by the second silicon material layer 52 is obtained. The formation method for the through-hole 521 is not particularly limited, and for example, any of various etching techniques (wet etching and dry etching) can be used.

### Through-Hole Formation Step

Subsequently, as shown in FIG. 12, at least one through-hole 421 is formed in the lid section 42, and the sacrificial layer 50 is exposed through the through-hole 421. The formation method for the through-hole 421 is not particularly limited, and for example, any of various etching techniques (wet etching and dry etching) can be used.

Subsequently, as shown in FIG. 13, a protective film 54 which protects the second silicon material layer 52 from wet etching in the hollow section formation step to be performed later is formed on the inner peripheral surface of the through-hole 521 and the opening end surface of the through-hole 521 of the second silicon material layer 52 using a sputtering method, a CVD method, or the like. Further, in a region which is not protected by the protective film 54, a resist mask M as an etching protective layer is formed using a sputtering method, a CVD method, or the like. The protective film 54 is placed so as not to overlap the through-hole 421 or a region 440 in which the through electrode 44 is formed of the upper surface of the second silicon material layer 52.

### Hollow Section Formation Step

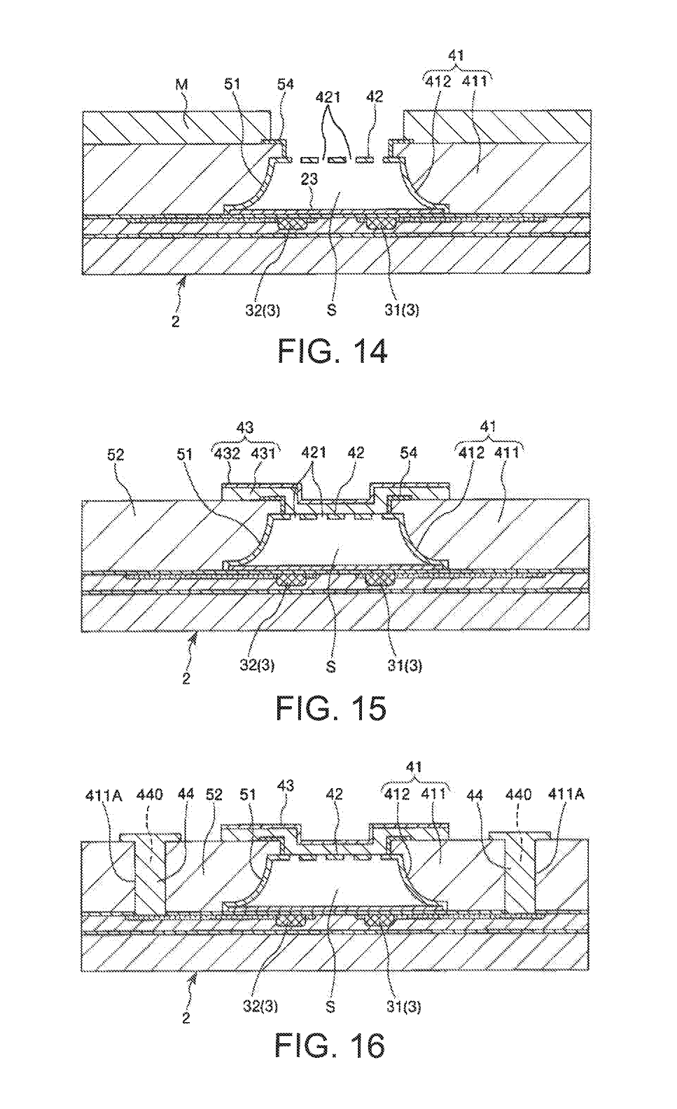

Subsequently, the base 2 is, for example, exposed to an etching solution such as buffered hydrofluoric acid. By doing this, the sacrificial layer 50 is release-etched through the through-hole 421, whereby the hollow section S is formed as shown in FIG. 14. At this time, the second insulating film 23 and the first silicon material layer 51, which surround the sacrificial layer 50 and are composed of polysilicon, function as an etching stopper. Then, after completion of this step, the resist mask M is removed.

### Sealing Step

Subsequently, as shown in FIG. 15, the hollow section S is brought into a vacuum state, and the sealing section 43 is formed on the lid section 42 to seal the through-hole 421. Specifically, first, the first sealing layer 431 is formed by depositing silicon on the lid section 42 using a sputtering method, a CVD method, or the like, and further, the second sealing layer 432 is formed by depositing silicon oxide on the first sealing layer 431 using a sputtering method, a CVD method, or the like. By doing this, the sealing section 43 which seals the through-hole 421 is obtained, and the hollow section S is hermetically sealed in a vacuum state. In this manner, by forming the sealing section 43 having a stacked structure of the first sealing layer 431 and the second sealing layer 432, the through-hole 421 can be more reliably sealed, and the air tightness of the hollow section S can be ensured.

Subsequently, the hollow section S is heated to about 800° C. to 1000° C., whereby the vacuum degree of the hollow section S is increased. Here, as described above, a material having a low melting point such as aluminum is not used in the steps up to this point, and therefore, the hollow section S can be heated to a temperature as high as about 800° C. to 1000° C. in this step. Therefore, the vacuum degree can be further increased.

### Through Electrode Placement Step

Subsequently, as shown in FIG. 16, a through-hole 411A is formed in the region 440 of the base section 411, and the through electrode 44 is formed by depositing aluminum in the formed through-hole 411A using a sputtering method, a CVD method, or the like.

### Surface Protective Film Placement Step

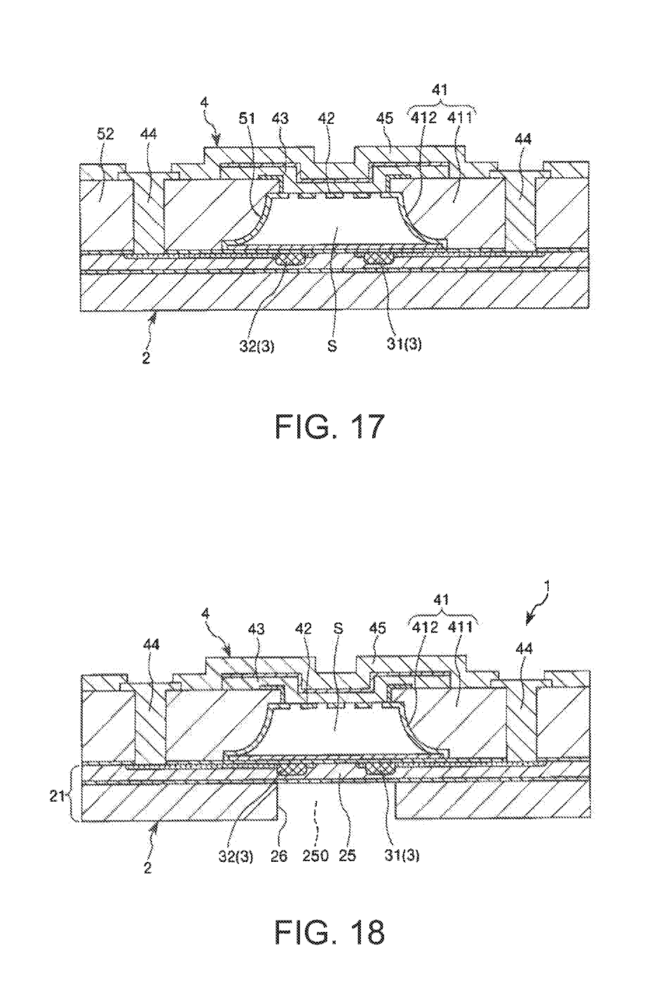

Subsequently, as shown in FIG. 17, the surface protective film 45 is formed by depositing silicon nitride on the second silicon material layer 52 and the sealing section 43 using a sputtering method, a CVD method, or the like.

### Diaphragm Formation Step

Subsequently, as shown in FIG. 18, the concave section 26 which opens to the lower surface of the SOI substrate 21 is formed in the diaphragm forming region 250, whereby the diaphragm 25 is obtained. The formation method for the concave section 26 is not particularly limited, however, the concave section 26 is formed by dry etching (silicon deep etching) in this embodiment.

As described above, the pressure sensor 1 is obtained. According to such a production method, the pressure sensor 1 capable of reducing the hysteresis and also capable of effectively reducing the decrease in the pressure detection accuracy can be easily produced. In the production method of this embodiment, the diaphragm formation step is performed in the end, however, the order of the diaphragm formation step is not particularly limited, and the diaphragm formation step may be performed, for example, subsequently to the preparation step.

### Second Embodiment

Next, a pressure sensor according to a second embodiment of the invention will be described.

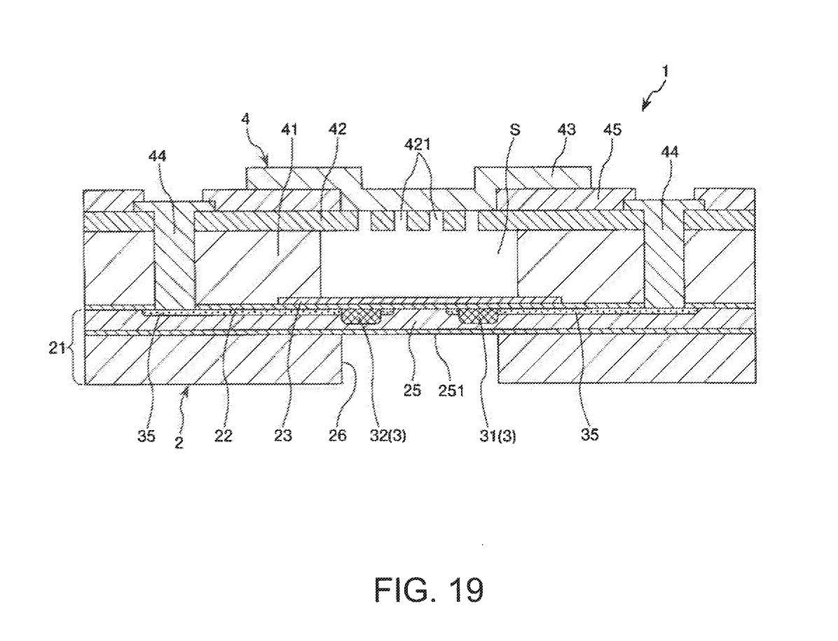

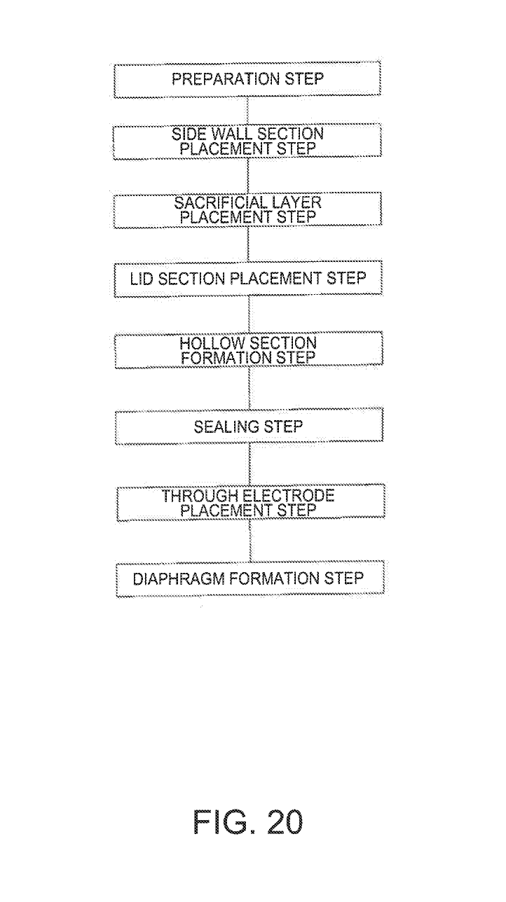

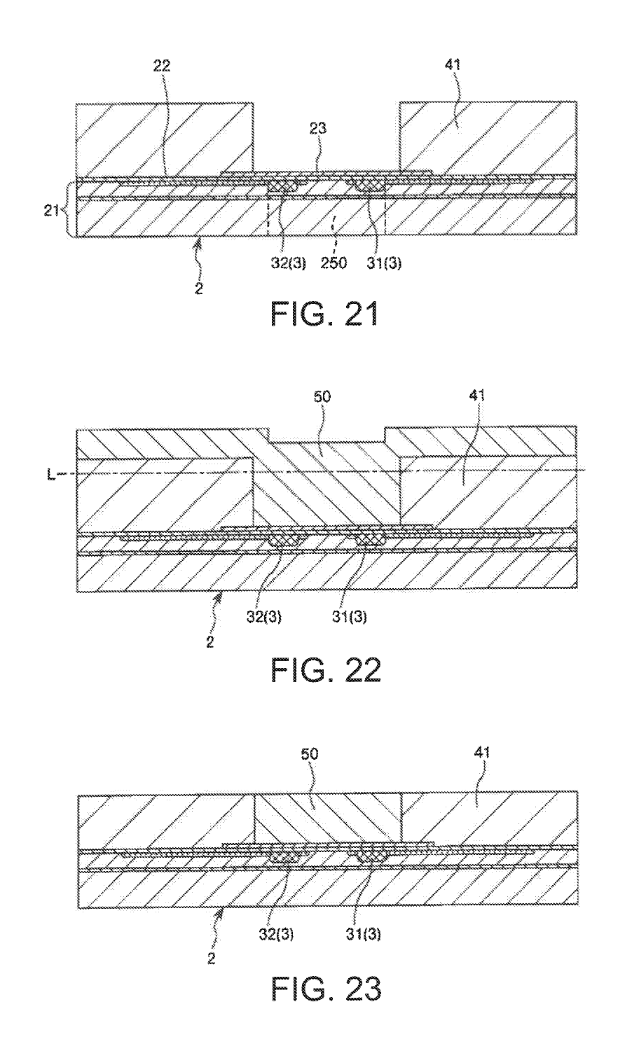

FIG. 19 is a cross-sectional view showing the pressure sensor according to the second embodiment of the invention. FIG. 20 is a flowchart showing a production method for the pressure sensor shown in FIG. 19. FIGS. 21 to 29 are each a cross-sectional view for illustrating the production method for the pressure sensor shown in FIG. 19.

Hereinafter, with respect to the pressure sensor according to the second embodiment, different points from the above-mentioned embodiment will be mainly described, and the description of the same matter will be omitted. The same components as those of the above-mentioned embodiment are denoted by the same reference numerals.

The pressure sensor according to this embodiment is the same as the pressure sensor according to the first embodiment described above except that the configuration of the surrounding structure is mainly different.

In the pressure sensor 1 shown in FIG. 19, the second insulating film 23 of the base 2 is composed of silicon nitride. Further, the surrounding structure 4 includes the frame-shaped side wall section 41 which is placed on the upper surface of the base 2 so as to surround the diaphragm 25 in a plan view, the lid section 42 which is placed so as to cover the opening on the upper side of the side wall section 41, and has the through-hole 421 communicating inside and outside the hollow section S, the sealing section 43 which is placed on the lid section 42 and seals the through-hole 421, the through electrode 44 which is provided passing through the side wall section 41 and is electrically connected to the wiring 35 of the pressure sensor section 3, and the surface protective film 45 which is placed on the surface of each of the side wall section 41 and the sealing section 43.

The side wall section 41 contains silicon, and is particularly composed of polysilicon in this embodiment. The constituent material of the side wall section 41 is not particularly limited as long as it can sufficiently ensure the etching selectivity to the sacrificial layer 50, and may be, for example, single-crystal silicon, amorphous silicon, silicon oxide, silicon nitride, or the like.

The lid section 42 is located on the ceiling of the hollow section S, and is placed so as to cover the opening on the upper side of the side wall section 41. Further, in the lid section 42, the through-hole 421 communicating inside and outside the hollow section S is provided. Such a lid section 42 contains a silicon material, and is particularly composed of polysilicon in this embodiment. However, the constituent material of the lid section 42 is not particularly limited as long as it can sufficiently ensure the etching selectivity to the sacrificial layer 50, and may be, for example, single-crystal silicon, amorphous silicon, silicon nitride, or the like.

In this manner, in the pressure sensor 1, each of the base 2, the side wall section 41, and the lid section 42 contains a silicon material, and therefore, the difference in the thermal expansion coefficient thereof can be decreased. Due to this, the hysteresis can be reduced, and the decrease in the pressure detection accuracy can be effectively reduced in the same manner as in the above-mentioned first embodiment.

Next, a production method for the pressure sensor 1 will be described. As shown in FIG. 20, the production method for the pressure sensor 1 includes a preparation step of preparing the SOI substrate 21 as the silicon substrate having the diaphragm forming region 250, a side wall section placement step of placing the frame-shaped side wall section 41 containing silicon on one surface side of the SOI substrate 21 so as to surround the diaphragm forming region 250 in a plan view, a sacrificial layer placement step of placing the sacrificial layer 50 inside the side wall section 41, a lid section placement step of placing the lid section 42 which has the through-hole 421 facing the sacrificial layer 50 and contains a silicon material on the side wall section 41 and the sacrificial layer 50 so as to cover the opening of the side wall section 41, a hollow section formation step of forming the hollow section S as the pressure reference chamber by removing the sacrificial layer 50 through the through-hole 421, a sealing step of sealing the through-hole 421 by placing the sealing section 43 on the lid section 42, a through electrode placement step of placing the through electrode 44, and a diaphragm formation step of forming the diaphragm 25 which is flexurally deformed by receiving a pressure in the diaphragm forming region 250 of the SOI substrate 21.

### Preparation Step

This step is the same as in the above-mentioned first embodiment, and therefore, the description thereof will be omitted.

### Side Wall Section Placement Step

First, as shown in FIG. 21, the frame-shaped side wall section 41 containing a silicon material is placed on the upper surface of the base 2 so as to surround the diaphragm forming region 250 in a plan view. The formation method for the side wall section 41 is not particularly limited, however, for example, first, a thick film is formed by depositing polysilicon on the upper surface of the base 2 using a sputtering method, a CVD method, or the like, and subsequently, this thick film is patterned by dry etching, whereby the side wall section 41 can be formed. As another formation method, first, a thin film is formed by depositing polysilicon on the upper surface of the base 2 using a sputtering method, a CVD method, or the like, and subsequently, the thin film is patterned into the plan view shape of the side wall section 41, and then, polysilicon is epitaxially grown from the patterned thin film, whereby the side wall section 41 can also be formed.

### Sacrificial Layer Placement Step

Subsequently, the sacrificial layer 50 is placed inside the side wall section 41. Specifically, first, as shown in FIG. 22, the sacrificial layer 50 is formed by depositing silicon oxide from the upper side of the base 2 using a sputtering method, a CVD method, or the like. This sacrificial layer 50 fills a space inside the side wall section 41 and also is stacked on the side wall section 41. Subsequently, for example, the sacrificial layer 50 is polished to the line L in the drawing from the upper side by CMP (chemical mechanical polishing) or the like, whereby the polishing is made to reach the side wall section 41. By doing this, as shown in FIG. 23, the sacrificial layer 50 above the side wall section 41 is removed, and also the upper surfaces of the sacrificial layer 50 and the side wall section 41 are aligned and flush with each other. Incidentally, the side wall section 41 is shaved and the height thereof is decreased in this step, and therefore, it is preferred to form the side wall section 41 which is higher than the designed value in the side wall section formation step to be performed before.

### Lid Section Placement Step

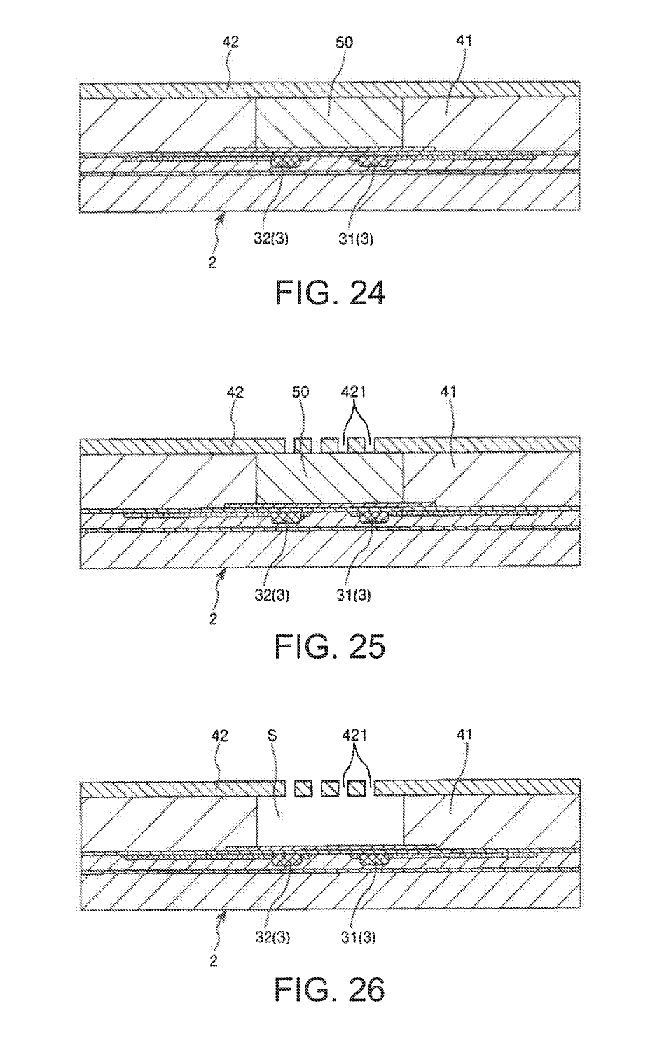

Subsequently, as shown in FIG. 24, polysilicon is deposited on the side wall surface 41 and the sacrificial layer 50 using a sputtering method, a CVD method, or the like. By doing this, the lid section 42 which covers the opening of the side wall section 41 (in other words, the upper surface of the sacrificial layer 50) is obtained. Subsequently, as shown in FIG. 25, at least one through-hole 421 is formed in the lid section 42, and the sacrificial layer 50 is exposed through the through-hole 421. The formation method for the through-hole 421 is not particularly limited, and for example, any of various etching techniques (wet etching and dry etching) can be used.

### Hollow Section Formation Step

Subsequently, the base 2 is, for example, exposed to an etching solution such as buffered hydrofluoric acid. By doing this, the sacrificial layer 50 is release-etched through the through-hole 421, whereby the hollow section S is formed as shown in FIG. 26.

### Sealing Step

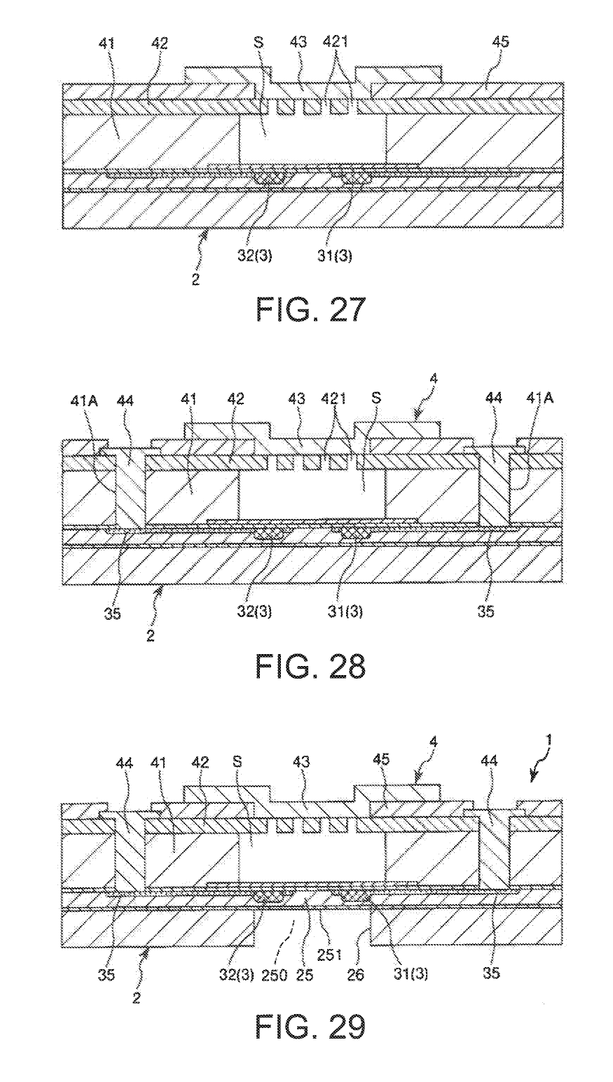

Subsequently, the surface protective film 45 is formed on the upper surface of the lid section 42 so as not to close the through-hole 421, and thereafter as shown in FIG. 27, the hollow section S is brought into a vacuum state, and the sealing section 43 is formed on the lid section 42 to seal the through-hole 421. By doing this, the hollow section S is hermetically sealed in a vacuum state. The sealing section 43 is obtained by depositing silicon on the lid section 42 using a sputtering method, a CVD method, or the like. The configuration of the sealing section 43 is not particularly limited, and may be, for example, a stacked structure in the same manner as in the above-mentioned first embodiment.

Subsequently, the hollow section S is heated to about 800° C. to 1000° C., whereby the vacuum degree of the hollow section S is increased. Here, as described above, a material having a low melting point such as aluminum is not used in the steps up to this point, and therefore, the hollow section S can be heated to a temperature as high as about 800° C. to 1000° C. in this step. Therefore, the vacuum degree can be further increased.

### Through Electrode Placement Step

Subsequently, as shown in FIG. 28, a through-hole 41A is formed in the side wall section 41, and the through electrode 44 is formed by depositing aluminum in the formed through-hole 41A using a sputtering method, a CVD method, or the like.

### Diaphragm Formation Step

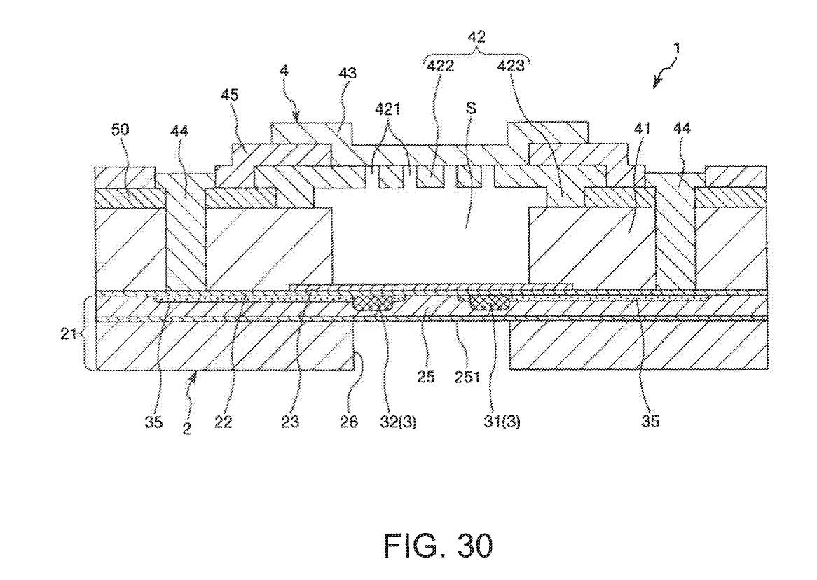

Subsequently, as shown in FIG. 29, the concave section 26 which opens to the lower surface of the SOI substrate 21 is formed in the diaphragm forming region 250, whereby the diaphragm 25 is obtained. The formation method for the concave section 26 is not particularly limited, however, the concave section 26 is formed by dry etching (silicon deep etching) in this embodiment.

As described above, the pressure sensor 1 is obtained. According to such a production method, the pressure sensor 1 capable of reducing the hysteresis and also capable of effectively reducing the decrease in the pressure detection accuracy can be easily produced.

Also according to such a second embodiment, the same effect as that of the above-mentioned first embodiment can be exhibited.

### Third Embodiment

Next, a pressure sensor according to a third embodiment of the invention will be described.

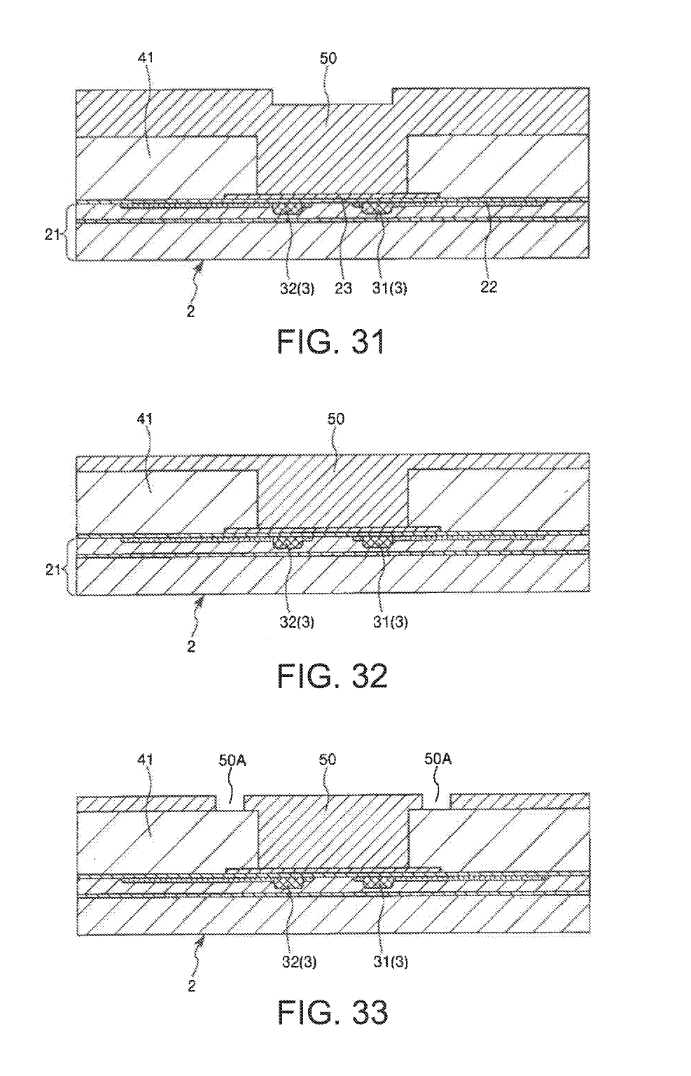

FIG. 30 is a cross-sectional view showing the pressure sensor according to the third embodiment of the invention. FIGS. 31 to 35 are each a cross-sectional view for illustrating a production method for the pressure sensor shown in FIG. 30.

Hereinafter, with respect to the pressure sensor according to the third embodiment, different points from the above-mentioned embodiment will be mainly described, and the description of the same matter will be omitted. The same components as those of the above-mentioned embodiment are denoted by the same reference numerals.

The pressure sensor according to this embodiment is the same as the pressure sensor according to the second embodiment described above except that the configuration of the surrounding structure is mainly different.

In the surrounding structure 4 of the pressure sensor 1 shown in FIG. 30, the lid section 42 includes the base section 422 which is placed so as to face the opening on the upper side of the side wall section 41 and has a through-hole 421, and a frame-shaped leg section 423 which is located between the base section 422 and the side wall section 41 and connects these sections. The leg section 423 is connected to the side wall section 41 in the entire circumference of the lower end portion thereof, and is connected to the base section 422 in the entire circumference of the upper end portion thereof.

Also according to such a pressure sensor 1, the hysteresis can be reduced and the decrease in the pressure detection accuracy can be effectively reduced in the same manner as in the above-mentioned first embodiment.

Next, a production method for the pressure sensor 1 will be described. The production method for the pressure sensor 1 includes a preparation step, a side wall section placement step, a sacrificial layer placement step, a lid section placement step, a hollow section formation step, a sealing step, a through electrode placement step, and a diaphragm formation step in the same manner as in the above-mentioned second embodiment.

### Preparation Step

This step is the same as in the above-mentioned second embodiment, and therefore, the description thereof will be omitted.

### Side Wall Section Placement Step

This step is the same as in the above-mentioned second embodiment, and therefore, the description thereof will be omitted.

### Sacrificial Layer Placement Step

Subsequently, the sacrificial layer 50 is placed inside the side wall section 41. Specifically, first, as shown in FIG. 31, the sacrificial layer 50 is formed by depositing silicon oxide on the base 2 using a sputtering method, a CVD method, or the like. This sacrificial layer 50 is disposed so as to fill a space inside the side wall section 41 and also cover the upper surface (that is, the surface on the opposite side to the SOI substrate 21) of the side wall section 41. Subsequently, for example, the sacrificial layer 50 is polished from the upper side by CMP (chemical mechanical polishing) or the like, whereby the upper surface of the sacrificial layer 50 is made a flat surface as shown in FIG. 32. At this time, the upper surface of the side wall section 41 is made not to be exposed from the sacrificial layer 50. By doing this, the upper surface of the side wall section 41 is not polished by CMP, and therefore, the side wall section 41 can be protected, and the roughness of the upper surface of the side wall section 41 can be reduced.

### Lid Section Placement Step

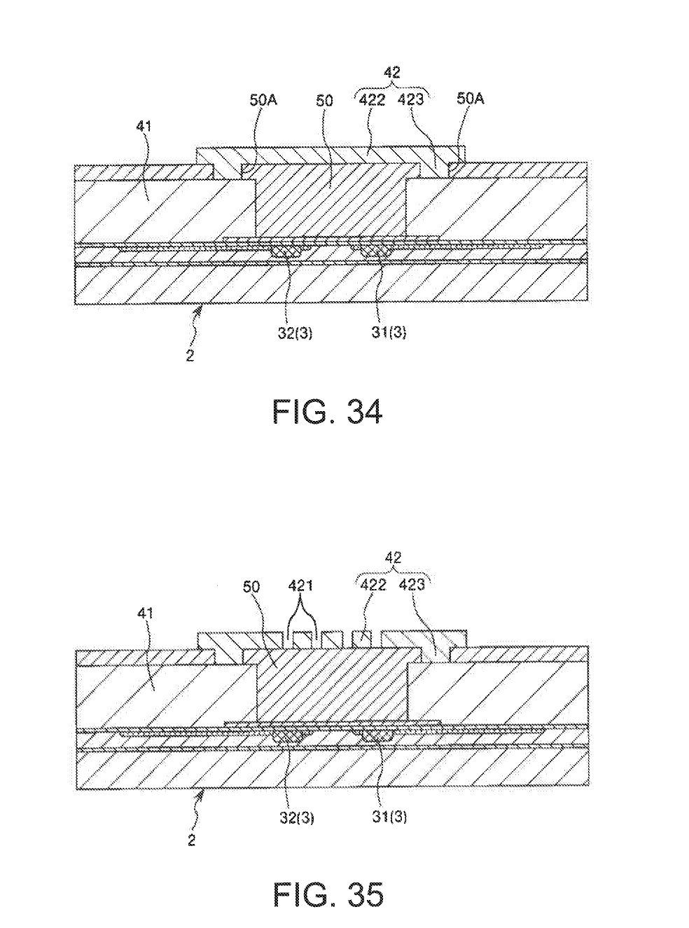

Subsequently, as shown in FIG. 33, a frame-shaped through-hole 50A facing the upper surface of the side wall section 41 is formed in a portion overlapping the side wall section 41 of the sacrificial layer 50. Subsequently, as shown in FIG. 34, the lid section 42 is placed in the frame-shaped through-hole 50A and on the sacrificial layer 50. The lid section 42 is obtained by depositing polysilicon using a sputtering method, a CVD method, or the like, and a portion located in the frame-shaped through-hole 50A becomes the leg section 423, and a portion located on the sacrificial layer 50 becomes the base section 422. Since the upper surface of the side wall section 41 is not roughened by CMP as described above, the adhesion between the upper surface of the side wall section 41 and the leg section 423 is high, and a gap is hardly generated between these sections. Due to this, in the subsequent hollow section formation step, the leakage of an etching solution from this portion can be effectively reduced. Subsequently, as shown in FIG. 35, at least one through-hole 421 is formed in the lid section 42.

### Hollow Section Formation Step

This step is the same as in the above-mentioned second embodiment, and therefore, the description thereof will be omitted.

### Sealing Step

This step is the same as in the above-mentioned second embodiment, and therefore, the description thereof will be omitted.

### Through Electrode Placement Step

This step is the same as in the above-mentioned second embodiment, and therefore, the description thereof will be omitted.

### Diaphragm Formation Step

This step is the same as in the above-mentioned second embodiment, and therefore, the description thereof will be omitted.

As described above, the pressure sensor 1 is obtained. According to such a production method, the pressure sensor 1 capable of reducing the hysteresis and also capable of effectively reducing the decrease in the pressure detection accuracy can be easily produced.

Also according to such a third embodiment, the same effect as that of the above-mentioned first embodiment can be exhibited.

### Fourth Embodiment

Next, an altimeter according to a fourth embodiment of the invention will be described.

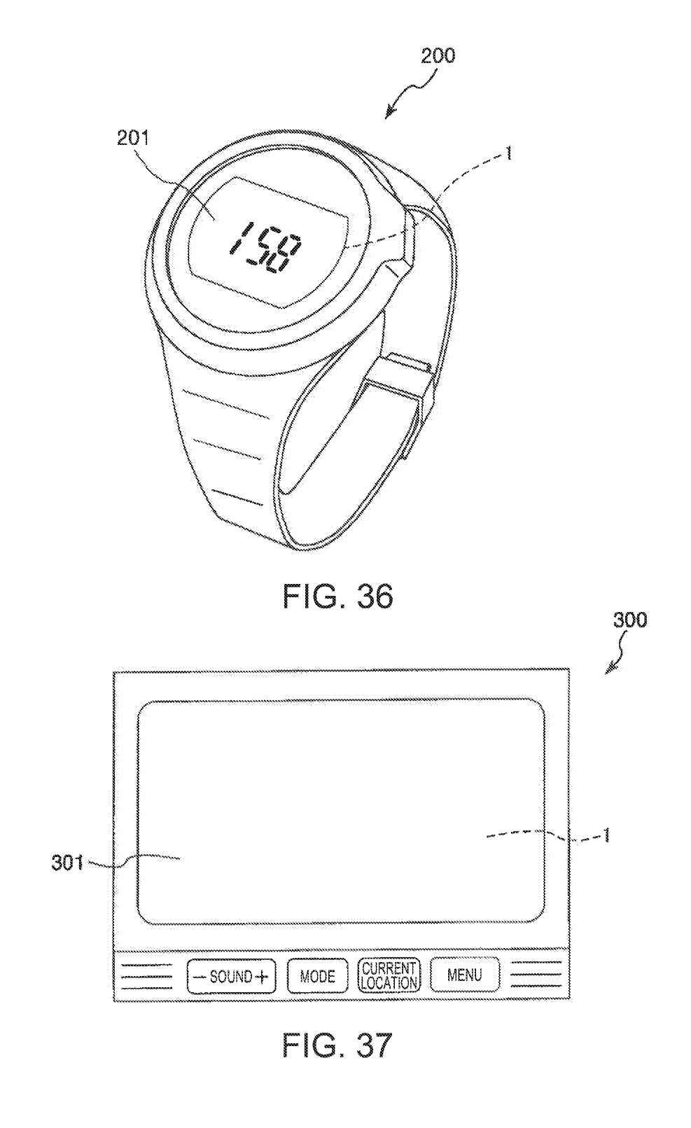

FIG. 36 is a perspective view showing one example of an altimeter according to the invention.

An altimeter 200 shown in FIG. 36 can be worn on the wrist like a wristwatch. In the altimeter 200, the pressure sensor 1 is mounted, and the altitude of the current location above sea level, the atmospheric pressure of the current location, or the like can be displayed on a display section 201. In this display section 201, various information such as a current time, the heart rate of a user, or weather can be displayed other than these. Such an altimeter 200 includes the pressure sensor 1 having excellent detection accuracy, and therefore can exhibit high reliability.

### Fifth Embodiment

Next, an electronic apparatus according to a fifth embodiment of the invention will be described.

FIG. 37 is a front view showing one example of an electronic apparatus according to the invention.

The electronic apparatus shown in FIG. 37 is a navigation system 300 including the pressure sensor 1. The navigation system 300 includes map information (not shown), a location information acquisition unit based on a GPS (Global Positioning System), a self-contained navigation unit based on a gyroscope, an accelerometer, and a vehicle speed data, the pressure sensor 1, and a display section 301 which displays given location information or route information.

According to this navigation system 300, in addition to the acquired location information, altitude information can be acquired by the pressure sensor 1. Due to this, by detecting the change in altitude by entering an elevated road from a general road (or vice versa), it is possible to determine whether a vehicle travels on the general road or the elevated road, and the navigation information of the actual traveling state can be provided to a user. Such a navigation system 300 includes the pressure sensor 1 having excellent detection accuracy and therefore can exhibit high reliability.

The electronic apparatus including the pressure sensor according to the invention is not limited to the above-mentioned navigation system, and can be applied to, for example, a personal computer, a cellular phone, a smartphone, a tablet terminal, a timepiece (including a smart watch), a medical apparatus (for example, an electronic thermometer, a sphygmomanometer, a blood glucose meter, an electrocardiographic apparatus, an ultrasonic diagnostic apparatus, or an electronic endoscope), various measurement apparatuses, meters and gauges (for example, meters and gauges for vehicles, aircrafts, and ships), a flight simulator, and the like.

### Sixth Embodiment

Next, a moving object according to a sixth embodiment of the invention will be described.

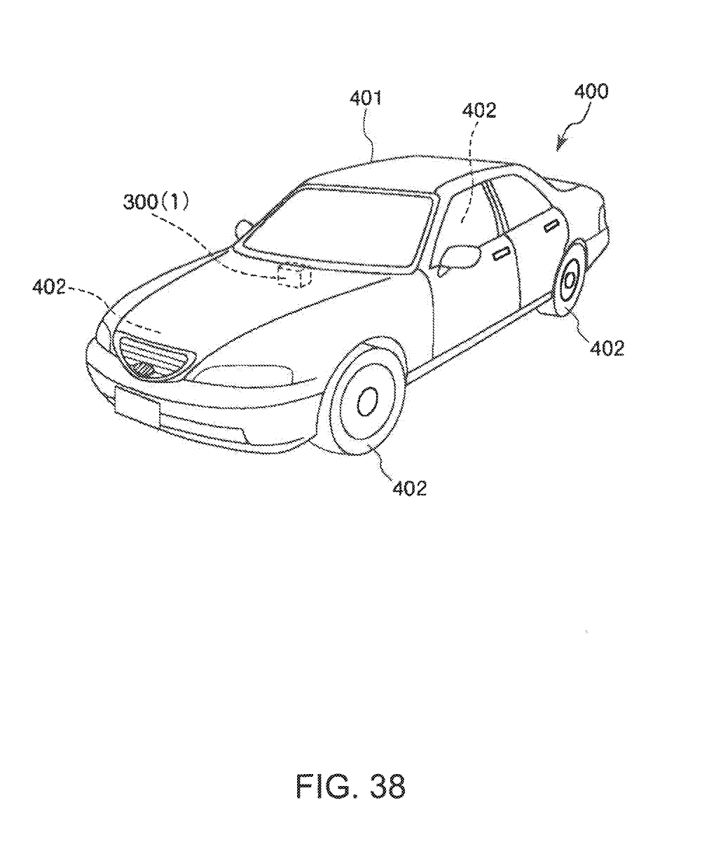

FIG. 38 is a perspective view showing one example of a moving object according to the invention,

The moving object shown in FIG. 38 is a car 400 including the pressure sensor 1. The car 400 includes a car body 401 and four wheels 402, and is configured to rotate the wheels 402 by a power source (engine) (not shown) provided in the car body 401. Such a car 400 is provided with the navigation system 300 including the pressure sensor 1 having excellent detection accuracy and therefore can exhibit high reliability.

Hereinabove, the pressure sensor, the production method for a pressure sensor, the altimeter, the electronic apparatus, and the moving object according to the invention have been described based on the respective embodiments shown in the drawings, however, the invention is not limited thereto, and the configuration of each section can be replaced with an arbitrary configuration having the same function. Further, another arbitrary component or step may be added, and also the respective embodiments may be appropriately combined with each other.

Further, in the above-mentioned embodiments, as the pressure sensor section, a pressure sensor section using a piezoresistive element is described, however, the pressure sensor is not limited thereto, and for example, a configuration using a flap-type vibrator, another MEMS vibrator such as a comb electrode, or a vibration element such as a crystal vibrator can also be used.

The entire disclosure of Japanese Patent Application No. 2016-050558, filed Mar. 15, 2016 is expressly incorporated by reference herein.

What is claimed is:

1. A pressure sensor, comprising:
a silicon substrate which has a diaphragm that is flexurally deformed by receiving a pressure;
a frame-shaped side wall section which is placed on one surface side of the silicon substrate so as to surround the diaphragm in a plan view;
a lid section which is placed so as to cover an opening of the side wall section and has a through-hole communicating inside and outside the side wall section;
a sealing section which is placed on the opposite side to the silicon substrate of the lid section and seals the through-hole; and
a pressure reference chamber which is defined by the silicon substrate, the side wall section, the lid section, and the sealing section, wherein
a portion on a surface side facing the pressure reference chamber of each of the side wall section and the lid section contains a silicon material.

2. The pressure sensor according to claim 1, wherein
the side wall section includes
a base section which contains silicon oxide, and
a coating layer which is placed on a surface of the base section so as to face the pressure reference chamber, and contains silicon.

3. The pressure sensor according to claim 2, wherein the coating layer and the lid section are formed as one body.

4. The pressure sensor according to claim 1, wherein the sealing section contains a silicon material.

5. The pressure sensor according to claim 1, wherein the side wall section has a tapered shape in which the width of the pressure reference chamber gradually decreases from the diaphragm side to the lid section side.

6. A production method for a pressure sensor, comprising:
preparing a silicon substrate which has a diaphragm forming region;
placing a sacrificial layer on one surface side of the silicon substrate so as to overlap the diaphragm forming region in a plan view;
placing a first silicon material layer containing a silicon material on a surface of the sacrificial layer;
placing a second silicon material layer containing a silicon material so as to cover the first silicon material layer;
removing a portion of the second silicon material layer, thereby exposing the first silicon material layer from the removed portion;
forming a through-hole facing the sacrificial layer in a portion exposed from the second silicon material layer of the first silicon material layer;
forming a pressure reference chamber by removing the sacrificial layer through the through-hole;
sealing the through-hole by placing a sealing section in the portion exposed from the second silicon material layer of the first silicon material layer; and
forming a diaphragm which is flexurally deformed by receiving a pressure in the diaphragm forming region of the silicon substrate.

7. The production method for a pressure sensor according to claim 6, wherein the sacrificial layer has a tapered shape in which the width thereof gradually decreases along a separating direction from the silicon substrate.

8. A production method for a pressure sensor, comprising:
preparing a silicon substrate which has a diaphragm forming region;
placing a frame-shaped side wall section containing a silicon material on one surface side of the silicon substrate so as to surround the diaphragm forming region in a plan view;
placing a sacrificial layer inside the side wall section;
placing a lid section which has a through-hole facing the sacrificial layer and contains a silicon material on the side wall section and the sacrificial layer so as to cover an opening of the side wall section;
forming a pressure reference chamber by removing the sacrificial layer through the through-hole;
sealing the through-hole by placing a sealing section on the lid section; and
forming a diaphragm which is flexurally deformed by receiving a pressure in the diaphragm forming region of the silicon substrate.

9. The production method for a pressure sensor according to claim 8, wherein
in the placing the sacrificial layer, the sacrificial layer is placed so as to fill the inside of the side wall section and also cover the surface on the opposite side to the silicon substrate of the side wall section, and
in the placing the lid section, a frame-shaped through-hole facing the side wall section is formed in a portion overlapping the side wall section of the sacrificial layer, and the lid section is placed in the frame-shaped through-hole and on the sacrificial layer.

10. An altimeter, comprising the pressure sensor according to claim 1.

11. An altimeter, comprising the pressure sensor according to claim 2.

12. An altimeter, comprising the pressure sensor according to claim 3.

13. An altimeter, comprising the pressure sensor according to claim 4.

14. An electronic apparatus, comprising the pressure sensor according to claim 1.

15. An electronic apparatus, comprising the pressure sensor according to claim 2.

16. An electronic apparatus, comprising the pressure sensor according to claim 3.

17. An electronic apparatus, comprising the pressure sensor according to claim 4.

18. A moving object, comprising the pressure sensor according to claim 1.

19. A moving object, comprising the pressure sensor according to claim 2.

20. A moving object, comprising the pressure sensor according to claim 3.
